(19) United States
(12) Patent Application Publication
(10) Pub. No.: US 2014/0120469 A1
(43) Pub. Date: May 1, 2014

(54) THERMAL ACID GENERATORS FOR USE IN PHOTORESIST

(71) Applicant: ROHM AND HAAS ELECTRONIC MATERIALS LLC, Marlborough, MA (US)

(72) Inventors: Gregory P. PROKOPOWICZ, Worcester, MA (US); Gerhard POHLERS, Needham, MA (US); Cong LIU, Shrewsbury, MA (US); Chunyi WU, Shrewsbury, MA (US); Cheng-Bai XU, Southborough, MA (US)

(73) Assignee: Rohm and Haas Electronic Materials LLC, Marlborough, MA (US)

(21) Appl. No.: 13/665,104

(22) Filed: Oct. 31, 2012

(51) Int. Cl. G03F 7/004; G03F 7/20

(52) U.S. Cl. CPC G03F 7/0045; G03F 7/20
USPC 430/270.1; 430/326

(57) ABSTRACT

New photoresist compositions are provided that comprise a component that comprises a thermal acid generator and a quencher. Preferred photoresists of the invention may comprise a resin with photoacid-labile groups; a photoacid generator compound; and at least one thermal acid generator and at least one quencher that can function to improve line width roughness and photospeed.

### FIELD

This invention relates to photoresist compositions that comprise thermal acid generators for improved line width roughness (LWR). Preferred photoresists of the invention may comprise a resin with photoacid-labile groups; a photoacid generator and a thermal acid generator as disclosed herein.

### BACKGROUND

Photoresists are photosensitive films for transfer of images to a substrate. They form negative or positive images. After coating a photoresist on a substrate, the coating is exposed through a patterned photomask to a source of activating energy, such as ultraviolet light, to form a latent image in the photoresist coating. The photomask has areas opaque and transparent to activating radiation that define an image desired to be transferred to the underlying substrate.

Known photoresists can provide features having resolution and size sufficient for many existing commercial applications. However for many other applications, the need exists for new photoresists that can provide highly resolved images of sub-quarter-micron (<0.25 μm) dimension.

Various attempts have been made to alter the make-up of photoresist compositions to improve performance of functional properties. Among other things, a variety of basic compounds have been reported for use in photoresist compositions. See U.S. Pat. Nos. 7,479,361; 7,534,554; and 7,592,126. See also U.S. 2011/0223535 and US 2012/0077120.

### SUMMARY

The present invention provides photoresist compositions comprising a resin, a photoacid generator, a thermal acid generator (“TAG”), and a basic component (“quencher”) present in molar excess (or equivalent excess; that is, an excess of equivalents of base) relative to the thermal acid generator. In certain embodiments, the thermal acid generator produces an acid having a pKa of 2.0 or less during subsequent (e.g., post-application or post-exposure) thermal treatment of a coating layer of the photoresist composition. Preferably, such the thermal acid generator compounds when formulated in a photoresist composition are radiation insensitive, i.e. the thermal acid generator compound does not produce acid during exposure to radiation (e.g. 193 nm) activating for a photoresist containing the thermal acid generator compound until an appropriate post-application thermal treatment.

In certain embodiments, the invention provides a photoresist composition comprising (a) a resin; (b) a photoacid generator; (c) a thermal acid generator; and (d) a basic component present in equivalent excess relative to the thermal acid generator.

In certain embodiments, the invention provides a photoresist composition comprising (a) a resin; (b) a photoacid generator; (c) a thermal acid generator that produces an acid having a pKa of 2.0 or less during thermal treatment of a coating layer of the photoresist composition; and (d) a basic component.

The thermal acid generator, upon thermal treatment, can generate strong acids capable of deblocking the acid labile polymer protecting groups of the photoresist composition in both the unexposed and exposed regions of the photoresist. In the unexposed region, the thermal acid generated will in part be neutralized by the base quencher (e.g., by forming a salt). In the exposed region, the thermally generated acid will deblock the protecting groups along with the photogenerated acid, improving line width roughness (LWR) and profile. In addition, TAG/quencher compositions may have improved photospeed compared to resist compositions without the TAG/quencher combination.

Preferred thermal acid generator compounds can produce acid at a temperature of 250° C., more preferably 150° C. or 100° C.

Photoresists of the invention may be either positive-acting or negative-acting. In a preferred aspect, photoresists of the invention used for short-wavelength imaging applications, such as 193 nm imaging. In a further preferred aspect, the photoresist is a chemically-amplified positive resist, including an acid catalyzed chemically amplified photoresist.

Particularly preferred photoresists of the invention may be used in immersion lithography applications.

We have found that use of a thermal acid generator and a basic component in a photoresist composition, including chemically-amplified photoresist compositions, can significantly enhance resolution of a relief image (for example, fine lines) of the resist. In particular, we have found that use of a thermal acid generator and a basic component as disclosed herein can impart significantly enhanced lithographic results, including relative to a comparable photoresist that is otherwise identical to the photoresist that does not include a thermal acid generator and a basic component. See for instance, the comparative data, which follows.

Methods are also provided for forming relief images of photoresist compositions of the invention (including patterned lines with sub sub-50 nm or sub-20 nm dimensions). Substrates such as a microelectronic wafer also are provided having coated thereon a photoresist composition of the invention. Other aspects are disclosed infra.

### BRIEF DESCRIPTION OF THE DRAWINGS

FIG. 1A compares a resist formulation with 6.381 mmoles N,N,N′,N′-tetra(2-hydroxyethyl)ethylenediamine (THEDA) or 12.763 mmoles of amine content. Ammonium triflate was added at 0, 3.5, 7.0, or 10.5 mmoles. There is an optimal level of TAG to balance the properties of LWR and profile. FIG. 1B shows a comparison of TAG verses a lower quencher loading to achieve the same photospeed value. The TAG samples performed better lithographically.

FIG. 2 compares larger acid anions, (Triflate, PFBuS, Ad-TFBS). The larger acid anion while having lower water leaching also gives a better resist profile and less footing. Thus, larger, lower diffusing anions may be advantageous. Photospeed with the TAG is ˜35% faster than without.

FIG. 3 compares TAG verses PAG using a triflate anion. Note the greater exposure latitude for the ammonium triflate salt compared to the photo generated triflic acid.

### DETAILED DESCRIPTION

Without being bound by theory, it is believed that the use of a thermal acid generators to generate strong acids capable of deblocking the acid labile polymer protecting groups in both the unexposed and exposed regions of the photoresist. In the unexposed region, the thermal acid generated will in part be neutralized by the base quencher forming a salt. In the exposed region, the thermally generated acid will deblock the protecting groups along with the photogenerated acid. We tested thermal acid generators (TAG) in a photoresist to determine whether the photospeed of a slow resist formulation could be improved. It was found that not only did photospeed improve, but also line width roughness (LWR) and profile were improved, especially at defocus verses a resist without TAG.

In a comparison of TAG with an equivalent loading of photo acid generator (PAG), the TAG sample outperformed the PAG sample in terms of profile and LWR. Simply decreasing the level of quencher to improve photospeed did not work as well as TAG.

In preferred embodiments, the TAG is loaded at a level less than the moles or equivalents of base from the quencher (basic component). If the amount of TAG were higher than the equivalents of base of the quencher (on the basis of equivalents of acid to equivalents of base), the entire resist film (both the exposed and unexposed areas) would be deblocked by the acid and therefore produce no image.

In a preferred aspect, photoresist compositions are provided that comprise a resin, a photoacid generator, a thermal acid generator (“TAG”), and a basic component (or “quencher”)

Preferred thermal acid generators (TAGs) of the invention for use in photoresists may be polymeric or non-polymeric, with non-polymeric TAGs preferred for many applications. Preferred TAGs have relatively low molecular weight, for example, a molecular weight of less than or equal to 3000, more preferably ≦2500, ≦2000, ≦1500, ≦1000, ≦800 or even more preferably ≦500. Certain suitable TAGs are known, e.g., for use in antireflective coatings for photolithography.

Preferred TAGs include ionic thermal acid generators, such as sulfonate salts, including fluorinated sulfonate salts. Preferred salts include ammonium salts. In preferred embodiments, the thermal acid generator produces an acid having a pKa of less than about 2 (or less than about 1, or less than about 0) upon thermal treatment. The pKa of the acid generated by a TAG may be known or can be determined by conventional methods (e.g., determination of the pKa in an aqueous solution). In preferred embodiments, the thermal acid generator does not contain an aromatic moiety. In preferred embodiments, the thermal acid generator comprises (or generates upon heating) an anion component having 1 or more carbon atoms.

Preferred TAGs can generate acid upon thermal treatment, e.g., during a post-application thermal treatment or a post-exposure thermal treatment of a coating layer of the photoresist composition. Preferred TAGs can generate acid upon thermal treatment at e.g. a 60-second temperature treatment of about 250° C., more preferably 150° C. or 100° C.

Preferred TAGs for use in the present photoresists and methods also may not significantly generate acid as a result of exposure of the photoresist to activating radiation such as 193 nm. Thus, preferably less than 40, 30, 20, 10 or 5 percent of the TAG present in a photoresist coating layer produce an acid upon a step of exposure of the photoresist layer to activating radiation; instead, the TAG generates acid upon the subsequent thermal treatment. It is also understood that a TAG of a photoresist is a distinct and different material than the photoacid generator of the photoresist. For instance, in preferred aspects, the TAG is suitably not an onium salt.

Specifically preferred TAGs for use in photoresist compositions as disclosed herein include the following:

Ammonium triflate;

Ammonium perfluorobutanesulfonate (PFBuS);

Ammonium Ad-TFBS [4-adamantanecarboxyl-1,1,2,2-tetrafluorobutane sulfonate];

Ammonium AdOH-TFBS [3-hydroxy-4-adamantanecarboxyl-1,1,2,2-tetrafluorobutane sulfonate];

Ammonium Ad-DFMS [Adamantanyl-methoxycarbonyl)-difluoromethanesulfonate];

Ammonium AdOH-DFMS [3-Hydroxyadamantanyl-methoxycarbonyl)-difluoromethanesulfonate];

Ammonium DHC-TFBSS [4-dehydrocholate-1,1,2,2-tetrafluorobutanesulfonate]; and

Ammonium ODOT-DFMS [Hexahydro-4,7-Epoxyisobenzofuran-1(3H)-one, 6-(2,2′-difluoro-2-sulfonatoacetic acid ester)].

Preferred quenchers of the invention for use in photoresists may be polymeric or non-polymeric, with non-polymeric quenchers preferred for many applications. Preferred quenchers have relatively low molecular weight, for example, a molecular weight of less than or equal to 3000, more preferably ≦2500, ≦2000, ≦1500, ≦1000, ≦800 or even more preferably ≦500.

Preferred quenchers include basic compounds capable of reacting with a thermally-generated acid from a TAG. Suitable quenchers are known in the art and include compounds such as amines, including polyamines, such as diamines, triamines, or tetraamines, as well as quaternary ammonium compounds, trialkylammonium compounds, amides, ureas, TBOC-blocked amines, and the like. Specifically preferred quenchers for use in photoresist compositions as disclosed herein include the following:

N,N,N′,N′-tetra(1-hydroxyethyl)ethylenediamine (THEDA);

triisopropanolamine;

N-allylcaprolactam;

N,N′-diacetylethylenediamine;

3-2 N,N,N′,N′-tetramethyltartardiamide;

3-3 Piperazine-1,4-dicarbaldehyde;

3-4 trans-N,N′-(cyclohexane-1,2-diyl)diacetamide;

3-5 N,N,N′,N′-tetramethylmalonamide;

3-6 N,N,N′,N′,-tetrabutylmalonamide;

TBOC-tris(hydroxymethyl)aminomethane (TBOC-TRIS);

TBOC-4-hydroxypiperidine (TBOC-4-HP);

Dodoecyldiethanolamine (DDEA); and

Stearyldiethanolamine (SDEA).

TAG and quencher compounds useful in the present invention are generally commercially available or can be readily synthesized.

Preferably, thermal acid generators and basic compounds (quenchers) of the invention are used in positive-acting or negative-acting chemically amplified photoresists, i.e. negative-acting resist compositions which undergo a photoacid-promoted crosslinking reaction to render exposed regions of a coating layer of the resist less developer soluble than unexposed regions, and positive-acting resist compositions which undergo a photoacid-promoted deprotection reaction of acid labile groups of one or more composition components to render exposed regions of a coating layer of the resist more soluble in an aqueous developer than unexposed regions. Ester groups that contain a tertiary non-cyclic alkyl carbon or a tertiary alicyclic carbon covalently linked to the carboxyl oxygen of the ester are generally preferred photoacid-labile groups of resins employed in photoresists of the invention. Acetal groups also are suitable photoacid-labile groups.

Photoresists of the invention typically comprise a resin binder (polymer), a photoactive component such as one or more photoacid generators, and at least one Tag and at least one quencher as disclosed herein. Preferably the resin binder has functional groups that impart alkaline aqueous developability to the photoresist composition. For example, preferred are resin binders that comprise polar functional groups such as hydroxyl or carboxylate. Preferably the resin binder is used in a resist composition in an amount sufficient to render the resist developable with an aqueous alkaline solution.

Preferred imaging wavelengths of the photoresists of the invention include sub-300 nm wavelengths, such as 248 nm, and more preferably sub-200 nm wavelengths, such as 193 nm and EUV.

Particularly preferred photoresists of the invention may be used in immersion lithography applications. See, for example, U.S. Pat. No. 7968268 to Rohm and Haas Electronic Materials for a discussion of preferred immersion lithography photoresists and methods. Preferred photoresists for use in immersion application may comprise a resin (which may be fluorinated and/or have photoacid-labile groups) that is separate (not covalently linked) and distinct from a primary resin that has photoacid-labile groups. Thus, the present invention includes in preferred aspects photoresists that comprise: 1) a first resin with photoacid-labile groups; 2) one or more photoacid generator compounds; 3) a second resin that is separate and distinct from the first resin, the second resin may be fluorinated and/or have photoacid-acid groups; and 4) one or more TAGs and one or more quenchers as disclosed herein.

Particularly preferred photoresists of the invention contain an imaging-effective amount of one or more PAGs and one or more TAGs and one or more quenchers as disclosed herein and a resin that is selected from the group of:

1) a phenolic resin that contains acid-labile groups that can provide a chemically amplified positive resist particularly suitable for imaging at 248 nm. Particularly preferred resins of this class include: i) polymers that contain polymerized units of a vinyl phenol and an alkyl(meth)acrylate, where the polymerized alkyl (meth)acrylate units can undergo a deblocking reaction in the presence of photoacid. Exemplary alkyl(meth)acrylates that can undergo a photoacid-induced deblocking reaction include e.g. t-butyl acrylate, t-butyl methacrylate, methyladamantyl acrylate, methyl adamantyl methacrylate, and other non-cyclic alkyl and alicyclic(meth)acrylates that can undergo a photoacid-induced reaction, such as polymers in U.S. Pat. Nos. 6,042,997 and 5,492,793, incorporated herein by reference; ii) polymers that contain polymerized units of a vinyl phenol, an optionally substituted vinyl phenyl (e.g. styrene) that does not contain a hydroxy or carboxy ring substituent, and an alkyl (meth)acrylate such as those deblocking groups described with polymers i) above, such as polymers described in U.S. Pat. No. 6,042,997, incorporated herein by reference; and iii) polymers that contain repeat units that comprise an acetal or ketal moiety that will react with photoacid, and optionally aromatic repeat units such as phenyl or phenolic groups;.

2) a resin that is substantially or completely free of phenyl groups that can provide a chemically amplified positive resist particularly suitable for imaging at sub-200 nm wavelengths such as 193 nm. Particularly preferred resins of this class include: i) polymers that contain polymerized units of a non-aromatic cyclic olefin (endocyclic double bond) such as an optionally substituted norbornene, such as polymers described in U.S. Pat. No. 5,843,624; ii) polymers that contain alkyl(meth)acrylate units such as e.g. t-butyl acrylate, t-butyl methacrylate, methyladamantyl acrylate, methyl adamantyl methacrylate, and other non-cyclic alkyl and alicyclic(meth)acrylates; such polymers have been described in U.S. Pat. No. 6,057,083. Polymers of this type may contain in preferred aspects certain aromatic groups such as hydroxynaphthyl.

Preferred resins for use in photoresists to be imaged at sub-200 nm, such as at 193 nm, comprises units of two or more of the following general formulae (I), (II) and (III):

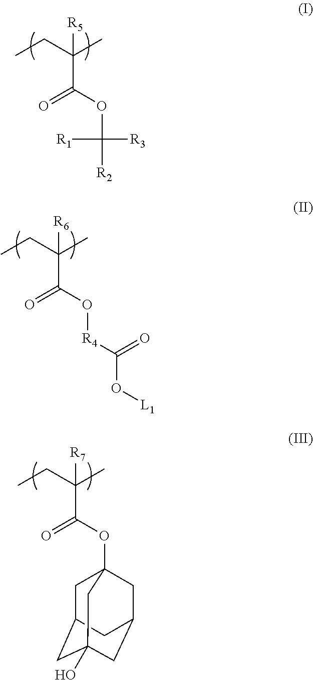

wherein: R₁, R2 and R3 are each optionally substituted (C₁-C₃₀)alkyl group; R₁, R₂ and R₃ may connect to form a ring; R₄ is a (C₁-C₃)alkylene group; L₁ is a lactone group; and R₅, R₆ and R₇ are each hydrogen, fluorine, (C1-C4)alkyl and (C1-C4)fluoroalkyl.

The unit of general formula (I) includes an acid labile group that undergoes a photoacid-promoted deprotection reaction on exposure to activating radiation and heat treatment. This allows for a switch in polarity of the matrix polymer, leading to a change in solubility of the polymer and photoresist composition in an organic developer. Suitable monomers for forming units of formula (I) include, for example, the following:

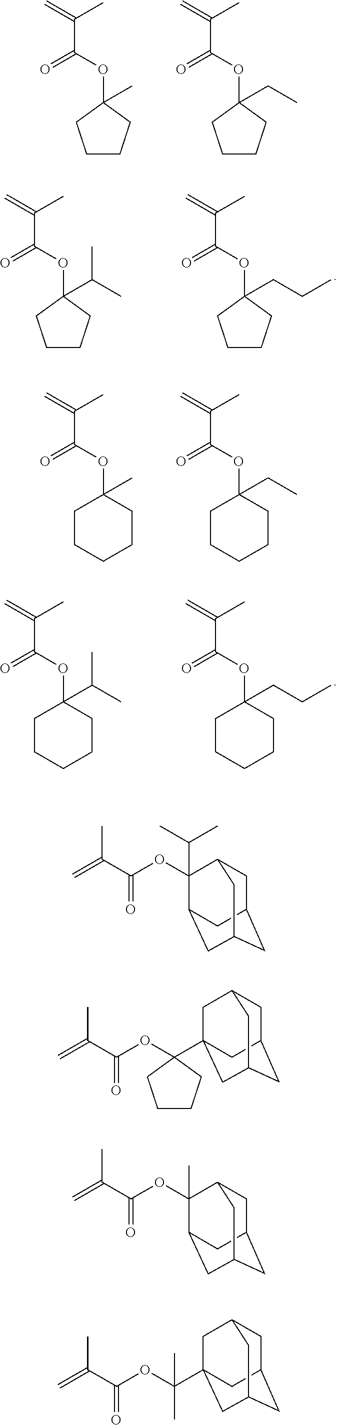

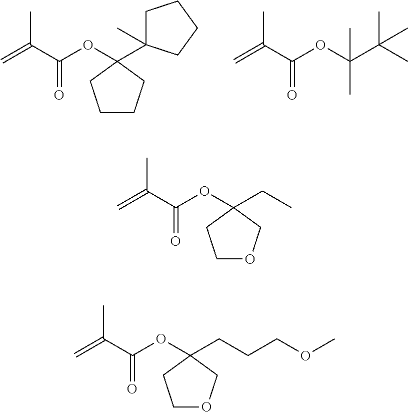

The unit of general formula (II) includes a lactone moiety effective to control the dissolution rate of the matrix polymer and photoresist composition. Suitable monomers for forming units of general formula (II) include, for example, the following:

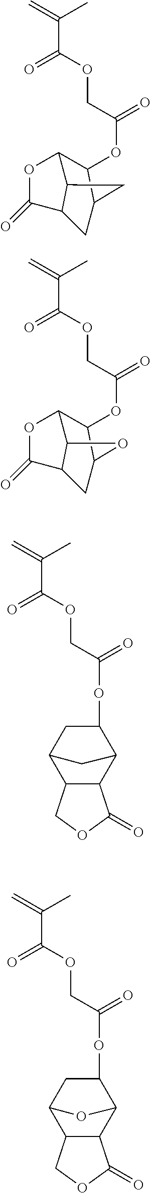

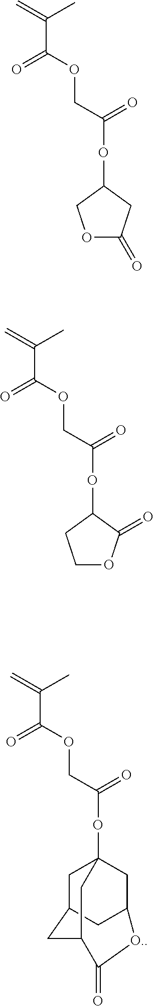

The unit of formula (III) provides a polar group, which enhances etch resistance of the resin and photoresist composition and provides additional means to control the dissolution rate of the resin and photoresist composition. Monomers for forming the unit of formula (III) include 3-hydroxy-1-adamantyl methacrylate (HAMA) and preferably 3-hydroxy-1-adamantyl acrylate (HADA).

The resin can include one or more additional units of general formulae (I), (II) and/or (III) different from the first units. Where additional such units are present in the resin, they will preferably include an additional leaving group-containing unit of formula (I) and/or a lactone-containing unit of formula (II).

In addition to the polymerized units described above, the resin can include one or more additional units which are not of general formula (I), (II) or (III). For example, a particularly suitable lactone group-containing unit is of the following general formula (IV):

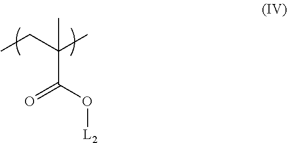

wherein: L₂ is a lactone group; and the unit of general formula (IV) is different from the unit of general formula (II). The following exemplary monomers are suitable for use in forming the additional lactone unit of general formula (IV):

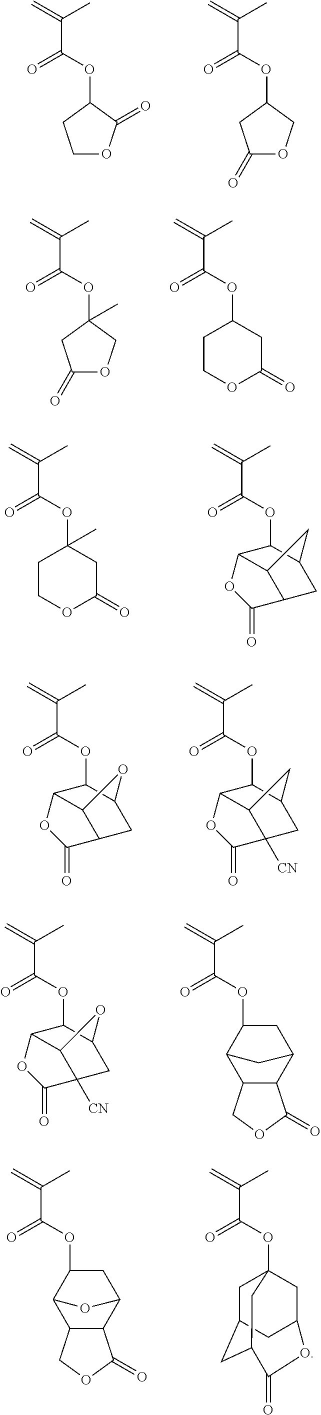

Preferably, L₁ in the unit of general formula (II) and L₂ in the unit of general formula (IV) are independently chosen from the following lactone groups:

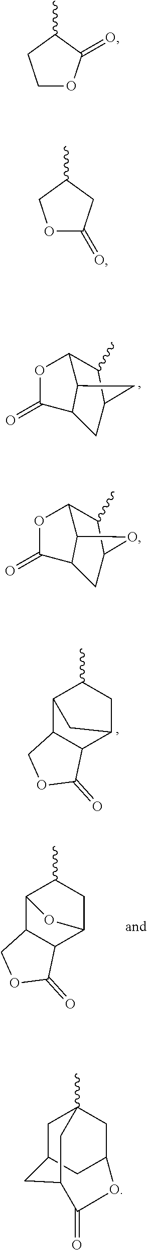

Typically, the additional units for the resin will include the same or similar polymerizable group as those used for the monomers used to form the units of general formula (I), (II) or (III), but may include other, different polymerizable groups in the same polymer backbone, such as those which contain polymerized units of vinyl or a non-aromatic cyclic olefin (endocyclic double bond) such as an optionally substituted norbornene. For imaging at sub-200 nm wavelengths such as 193 nm, the resin is typically substantially free (that is, less than 15 mole %) of phenyl, benzyl or other aromatic groups where such groups are highly absorbing of the radiation. Suitable additional monomeric units for the polymer include, for example, one or more of the following: monomeric units containing ethers, lactones or esters, such as 2-methyl-acrylic acid tetrahydro-furan-3-yl ester, 2-methyl-acrylic acid 2-oxo-tetrahydro-furan-3-yl ester, 2-methyl-acrylic acid 5-oxo-tetrahydro-furan-3-yl ester, 2-methyl-acrylic acid 3-oxo-4,10-dioxa-tricyclo[5.2.1.02,6]dec-8-yl ester, 2-methyl-acrylic acid 3-oxo-4-oxa-tricyclo[5.2.1.02,6]dec-8-yl ester, 2-methyl-acrylic acid 5-oxo-4-oxa-tricyclo[4.2.1.03,7]non-2-yloxycarbonylmethyl ester, acrylic acid 3-oxo-4-oxa-tricyclo[5.2.1.02,6]dec-8-yl ester, 2-methyl-acrylic acid 5-oxo-4-oxa-tricyclo[4.2.1.03,7]non-2-yl ester, and 2-methyl-acrylic acid tetrahydro-furan-3-yl ester; monomeric units having polar groups such as alcohols and fluorinated alcohols, such as 2-methyl-acrylic acid 3-hydroxy-adamantan-1-yl ester, 2-methyl-acrylic acid 2-hydroxy-ethyl ester, 6-vinyl-naphthalen-2-ol, 2-methyl-acrylic acid 3,5-dihydroxy-adamantan-1-yl ester, 2-methyl-acrylic acid 6-(3,3,3-trifluoro-2-hydroxy-2-trifluoromethyl-propyl)-bicyclo[2.2.1]hept-2-yl, and 2-bicyclo [2.2.1] hept-5-en-2-ylmethyl-1,1,1,3,3,3-hexafluoro-propan-2-ol; monomeric units having acid labile moieties, for example, ester groups that contain a tertiary non-cyclic alkyl carbon such as t-butyl, or a tertiary alicyclic carbon such as methyladamantyl or ethylfenchyl covalently linked to a carboxyl oxygen of an ester of the polymer, 2-methyl-acrylic acid 2-(1-ethoxy-ethoxy)-ethyl ester, 2-methyl-acrylic acid 2-ethoxymethoxy-ethyl ester, 2-methyl-acrylic acid 2-methoxymethoxy-ethyl ester, 2-(1-ethoxy-ethoxy)-6-vinyl-naphthalene, 2-ethoxymethoxy-6-vinyl-naphthalene, and 2-methoxymethoxy-6-vinyl-naphthalene. The additional units if used are typically present in the polymer in an amount of from 10 to 30 mol %.

Exemplary preferred resins include, for example, the following:

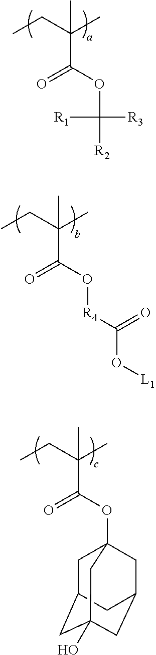

wherein: 0.3<a<0.7; 0.3<b<0.6; and 0.1<c<0.3;

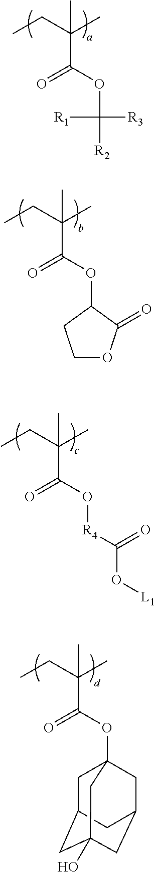

wherein: 0.3<a<0.7; 0.1<b<0.4; 0.1<c<0.4, and 0.1<d<0.3.

Blends of two or more resins can be used in the compositions of the invention. The resin is present in the resist composition in an amount sufficient to obtain a uniform coating of desired thickness. Typically, the resin is present in the composition in an amount of from 70 to 95 wt % based on total solids of the photoresist composition. Because of improved dissolution properties of the resin in organic developers, useful molecular weights for the resin are not limited to lower values, but cover a very broad range. For example, the weight average molecular weight M_{w} of the polymers is typically less than 100,000, for example, from 5000 to 50,000, more typically from 6000 to 30,000 or from 7,000 to 25,000.

Suitable monomers used in forming the resins are commercially available and/or can be synthesized using known methods. The resins can readily be synthesized by persons skilled in the art using the monomers with known methods and other commercially available starting materials.

Photoresists of the invention also may comprise a single PAG or a mixture of distinct PAGs, typically a mixture of 2 or 3 different PAGs, more typically a mixture that consists of a total of 2 distinct PAGs. The photoresist composition comprises a photoacid generator (PAG) employed in an amount sufficient to generate a latent image in a coating layer of the composition upon exposure to activating radiation. For example, the photoacid generator will suitably be present in an amount of from 1 to 20 wt % based on total solids of the photoresist composition. Typically, lesser amounts of the PAG will be suitable for chemically amplified resists as compared with non-chemically amplified materials.

Suitable PAGs are known in the art of chemically amplified photoresists and include, for example: onium salts, for example, triphenylsulfonium trifluoromethanesulfonate, (p-tert-butoxyphenyl)diphenylsulfonium trifluoromethanesulfonate, tris(p-tert-butoxyphenyl)sulfonium trifluoromethanesulfonate, triphenylsulfonium p-toluenesulfonate; nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine.

Photoresists of the invention comprise one or more TAGs and one or more quenchers as disclosed herein in a wide amount range. For example, the TAG can be present in an amount such as from 0.005 to 15 wt %, based on the weight of the PAG, preferably from 0.01 to 15 wt %, and even more preferably from 0.01 to 10 wt %. The TAG is suitably used in amounts of 0.01, 0.05, 0.1, 0.02, 0.3, 0.4, 0.5 or 1 to 10 or 15 wt % relative to the PAG, and more typically amounts of 0.01, 0.05, 0.1, 0.02, 0.3, 0.4, 0.5 or 1 to 5, 6, 7, 8, 9 or 10 weight percent.

The amount of TAG is less than the amount of quencher (on an equivalent basis); that is, the ratio of equivalents of TAG to equivalents of base from the quencher is less than 1. In certain embodiments, the ratio of equivalents of TAG to equivalents of base from the quencher (e.g., equivalents of amine, e.g., when a polyamine quencher or a mixture of quenchers is used) is from about 0.1 to about 0.9, preferably from about 0.20 to 0.60. An “equivalent of base” in a quencher means an equivalent of a moiety capable of acting as a base for a given TAG. Thus, for example, a polyamine quencher having two basic nitrogen atoms would have two equivalents of base per molecule (or mole) of polyamine, but a non-basic nitrogen atom would not be considered to be an equivalent of base for purposes of this disclosure. A “basic nitrogen atom” refers to a nitrogen atom in which the pKa of its corresponding conjugate base (protonated form) is at least about 5.0 (or, in some embodiments, at least about 6.0, 7.0, 8.0, 9.0, 10.0 or 11.0). As used herein, the term “pKₐ” is used in accordance with its art recognized meaning, that is, pKₐ is the negative log (to the base 10) of the dissociation constant of the conjugate base of the basic (quencher) compound in aqueous solution at about room temperature. It will be appreciated, however, that the environments in which the quencher compounds of the invention are typically used, namely in organic-based photoacid-generating compositions, are different than the aqueous solutions in which the above pKₐ values are determined. Hence, quenchers compounds (or basic nitrogen atoms in quencher compounds) having pKₐ values somewhat outside the above described preferred ranges also may be suitable for purposes of the invention.

The present photoresist compositions typically comprise a solvent. Suitable solvents include, for example: glycol ethers such as 2-methoxyethyl ether(diglyme), ethylene glycol monomethyl ether, and propylene glycol monomethyl ether; propylene glycol monomethyl ether acetate; lactates such as methyl lactate and ethyl lactate; propionates such as methyl propionate, ethyl propionate, ethyl ethoxy propionate and methyl-2-hydroxy isobutyrate; Cellosolve esters such as methyl Cellosolve acetate; aromatic hydrocarbons such as toluene and xylene; and ketones such as acetone, methylethyl ketone, cyclohexanone and 2-heptanone. A blend of solvents such as a blend of two, three or more of the solvents described above also are suitable. The solvent is typically present in the composition in an amount of from 90 to 99 wt %, more typically from 95 to 98 wt %, based on the total weight of the photoresist composition.

The photoresist compositions can also include other optional materials. For example, the compositions can include one or more of actinic and contrast dyes, anti-striation agents, plasticizers, speed enhancers, sensitizers, and the like. Such optional additives if used are typically present in the composition in minor amounts such as from 0.1 to 10 wt % based on total solids of the photoresist composition.

The photoresists of the invention are generally prepared following known procedures. For example, a photoresist composition of the invention can be prepared by dissolving the components of the photoresist in a suitable solvent. The resin binder component of photoresists resists of the invention are typically used in an amount sufficient to render an exposed coating layer of the resist developable such as with an aqueous alkaline solution. More particularly, a resin binder will suitably comprise 50 to 90 weight percent of total solids of the resist. The photoactive component should be present in an amount sufficient to enable generation of a latent image in a coating layer of the resist. More specifically, the photoactive component will suitably be present in an amount of from 1 to 40 weight percent of total solids of a photoresist. Typically, lesser amounts of the photoactive component will be suitable for chemically amplified resists.

The desired total solids content of the present photoresist compositions will depend on factors such as the particular polymers in the composition, final layer thickness and exposure wavelength. Typically the solids content of the photoresist varies from 1 to 10 wt %, more typically from 2 to 5 wt %, based on the total weight of the photoresist composition.

Preferred negative-acting compositions of the invention comprise a mixture of materials that will cure, crosslink or harden upon exposure to acid, and a photoactive component of the invention. Particularly preferred negative acting compositions comprise a resin binder such as a phenolic resin, a crosslinker component and a photoactive component of the invention. Such compositions and the use thereof has been disclosed in European Patent Applications 0164248 and 0232972 and in U.S. Pat. No. 5,128,232 to Thackeray et al. Preferred phenolic resins for use as the resin binder component include novolaks and poly(vinylphenol)s such as those discussed above. Preferred crosslinkers include amine-based materials, including melamine, glycolurils, benzoguanamine-based materials and urea-based materials. Melamine-formaldehyde resins are generally most preferred. Such crosslinkers are commercially available, e.g. the melamine resins sold by American Cyanamid under the trade names Cymel 300, 301 and 303. Glycoluril resins are sold by American Cyanamid under trade names Cymel 1170, 1171, 1172, urea-based resins are sold under the trade names of Beetle 60, 65 and 80, and benzoguanamine resins are sold under the trade names Cymel 1123 and 1125.

The photoresists of the invention can be used in accordance with known procedures. Though the photoresists of the invention may be applied as a dry film, they are preferably applied on a substrate as a liquid coating composition, dried by heating to remove solvent preferably until the coating layer is tack free, exposed through a photomask to activating radiation, optionally post-exposure baked to create or enhance solubility differences between exposed and nonexposed regions of the resist coating layer, and then developed preferably with an aqueous alkaline developer to form a relief image. The substrate on which a resist of the invention is applied and processed suitably can be any substrate used in processes involving photoresists such as a microelectronic wafer. For example, the substrate can be a silicon, silicon dioxide or aluminum-aluminum oxide microelectronic wafer. Gallium arsenide, ceramic, quartz or copper substrates may also be employed. Substrates used for liquid crystal display and other flat panel display applications are also suitably employed, for example, glass substrates, indium tin oxide coated substrates and the like. A liquid coating resist composition may be applied by any standard means such as spinning, dipping or roller coating.

The exposure energy should be sufficient to effectively activate the photoactive component of the radiation sensitive system to produce a patterned image in the resist coating layer. Suitable exposure energies typically range from 1 to 300 mJ/cm². As discussed above, preferred exposure wavelengths include sub-200 nm such as 193 nm.

The photoresist layer (with overcoated barrier composition layer, if present) may be preferably exposed in an immersion lithography system, i.e. where the space between the exposure tool (particularly the projection lens) and the photoresist coated substrate is occupied by an immersion fluid, such as water or water mixed with one or more additives such as cesium sulfate which can provide a fluid of enhanced refractive index. Preferably the immersion fluid (for example, water) has been treated to avoid bubbles, for example water can be degassed to avoid nanobubbles.

References herein to “immersion exposing” or other similar term indicates that exposure is conducted with such a fluid layer (for example, water or water with additives) interposed between an exposure tool and the coated photoresist composition layer.

After exposure, a thermal treatment is typically employed for chemically-amplified photoresists. Suitable post-exposure bake temperatures are from about 50° C. or greater, more specifically from 50 to 140° C. For an acid-hardening negative-acting resist, a post-development bake may be employed if desired at temperatures of from 100 to 150° C. for several minutes or longer to further cure the relief image formed upon development. After development and any post-development cure, the substrate surface bared by development may then be selectively processed, for example chemically etching or plating substrate areas bared of photoresist in accordance with procedures known in the art. Suitable etchants include a hydrofluoric acid etching solution and a plasma gas etch such as an oxygen plasma etch.

The invention also provide methods for forming relief images of the photoresists of the invention, including methods for forming highly resolved patterned photoresist images (for example, a patterned line having essentially vertical sidewalls) of sub-quarter μm dimensions or less, such as sub-0.2 or sub-0.1 μm dimensions.

The invention further provides articles of manufacture comprising substrates such as a microelectronic wafer or a flat panel display substrate having coated thereon the photoresists and relief images of the invention.

### EXAMPLE 1

### Preparation of Photoresist Composition (Resist A)

3.181 grams of a ArF photoresist polymer composed of 20/20/30/20/10 ECPMA/IAM/aGBLMA/ODOTMA/HAMA at 10 k Mw was added into a 120 mL glass container.

0.249 grams of TBPDPS-Ad-DFMS PAG and 0.240 grams of TPS-AdOH-DFMS PAG was then added.

29.530 grams of PGMEA solvent along with 3.737 grams of HBM solvent was added to the polymer and PAG.

5.881 grams of THEDA as a 1 wt % solution in PGMEA, 0.607 grams of an embedded barrier layer as a 3.5 wt % solution in PGMEA and 0.686 grams of ammonium triflate as a 5 wt % solution is HBM was added.

The sample was agitated overnight until all the dry components were dissolved and then filtered through a 0.1 um UPE filter.

Resists having differing amounts of TAG or quencher (see Tables 1 and 2) were prepared analogously.

### EXAMPLE 2

### Lithographic Processing of Photoresists

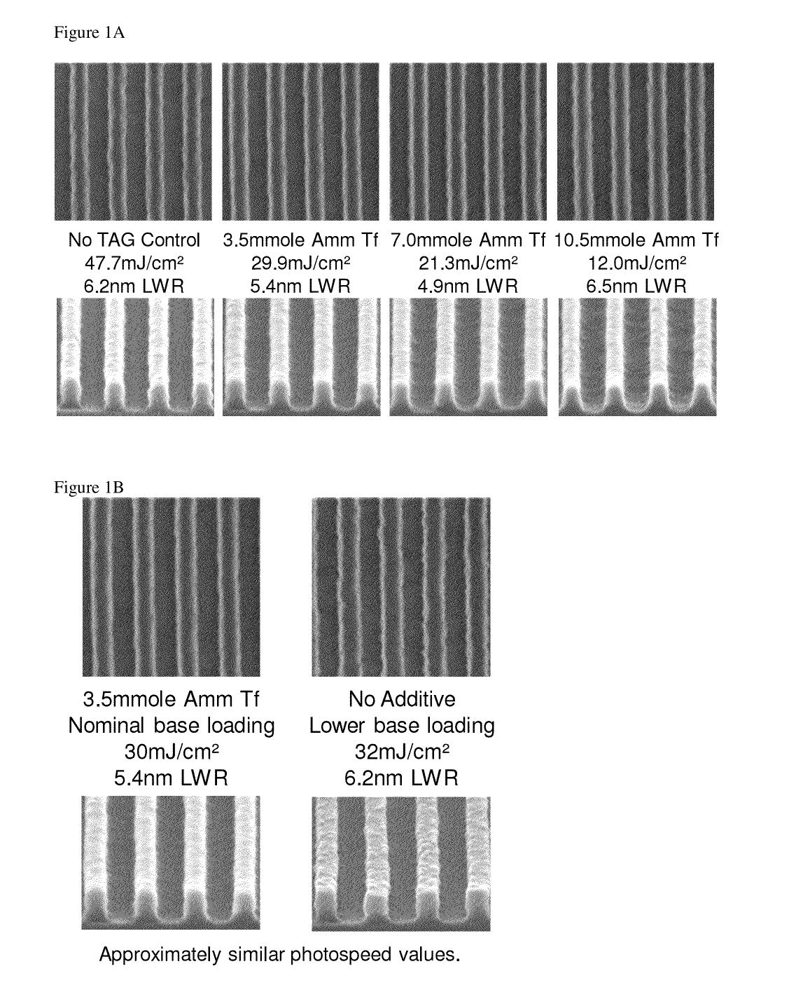

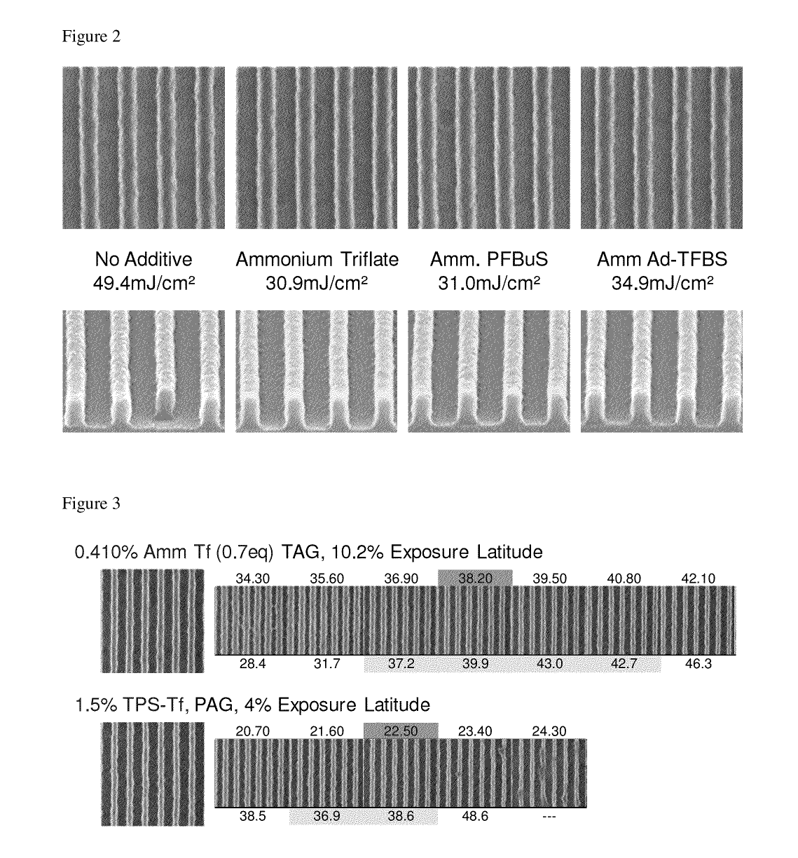

For the photoresist compositions for which the results are shown in FIGS. 1 and 2, the conditions for lithographic processing were as follows:

Non-Immersion Process Conditions:
Substrate: 200 mm Silicon
Underlayer: 200 nm AR2470 (235° C./60 sec.)
Silicon ARC: 38 nm (225° C./60 sec)
Resist: 120 nm (120° C./60 sec. SB)
Reticle: Binary
Dry Exposure: ASML/1100, 0.75NA, Dipole 35, 0.89/0.64 o/i
PEB: 100° C./60 sec.
Develop: LD-30s, MF-26A

### EXAMPLE 3

### Lithographic Processing of Photoresists

For the photoresist composition for which the results are shown in FIG. 3, the conditions for lithographic processing were as follows:

Immersion Process Conditions:
Substrate: 200 mm Silicon
Underlayer: 74 nm AR40A (205° C./60 sec.)
ARC: 22 nm (205° C./60 sec)
Resist: 105 nm (95° C./60 sec. SB)
Topcoat: 35 nm (90° C./60 sec.)
Reticle: Binary
Immersion Exposure: ASML/1900i, 1.35NA, Dipole 90, 0.95/0.75 o/i
PEB: 100° C./60 sec.
Develop: GP-30s, MF-26A

### EXAMPLE 4

### Lithographic Processing of Photoresists

Each of the photoresists (see Example 1) was separately spin coated on a bottom antireflective coating (see Examples 2 and 3) over 200 mm silicon wafers and softbaked. The coated wafer is exposed and then post-exposure baked (PEB), as described in Examples 2 and 3. The coated wafers are then treated to develop the imaged resist layer as described in Examples 2 and 3.

Line Width Roughness (LWR) was determined by processing the image captured by top-down scanning electron microscopy (SEM) using a Hitachi CG4000 CD-SEM, operating at an accelerating voltage of 500 volts (V), probe current of 5.0 picoamperes (pA), using 250 kx magnification. LWR was measured over a 400nm line length in steps of 5 nm, and reported as the average for the measured region.

Results are shown in FIGS. 1-3 and set forth in the following Tables.

TABLE 1

| Resist | TAG | Quencher | Photospeed | LWR (nm) |
|---|---|---|---|---|
| Control | None | THEDA, | 47.7 mJ/cm² | 6.2 |
| | | 6.381 mmol | | |
| | | (12.762 | | |
| | | moles amine) | | |
| A | Ammonium | THEDA, | 29.9 mJ/cm² | 5.4 |
| | triflate, 3.5 mmol | 6.381 mmol | | |
| | | (12.762 | | |
| | | moles amine) | | |
| B | Ammonium | THEDA, | 21.3 mJ/cm² | 4.9 |
| | triflate, 7.0 mmol | 6.381 mmol | | |
| | | (12.762 | | |
| | | moles amine) | | |
| C | Ammonium | THEDA, | 12.0 mJ/cm² | 6.5 |
| | triflate, | 6.381 mmol | | |
| | 10.5 mmol | (12.762 | | |
| | | moles amine) | | |
| D | Ammonium | “Nominal base | 30 mJ/cm² | 5.4 |
| | triflate, 3.5 mmol | loading”: | | |
| | | THEDA, | | |
| | | 6.381 mmol | | |
| | | (12.762 | | |
| | | moles amine) | | |
| E | None | “Lower base | 32 mJ/cm² | 6.2 |
| | | loading”: | | |
| | | THEDA, | | |
| | | 4.467 mmol | | |
| | | (8.934 | | |
| | | moles amine) | | |

TABLE 2

| Resist | TAG | Quencher | Photospeed |
|---|---|---|---|
| Control | None | THEDA, 6.381 mmol | 49.4 mJ/cm² |
| | | (12.762 | |
| | | moles amine) | |
| A | Ammonium | THEDA, 6.381 mmol | 30.9 mJ/cm² |
| | triflate, 3.5 mmol | (12.762 | |
| | | moles amine) | |
| B | Ammonium | THEDA, 6.381 mmol | 31.0 mJ/cm² |
| | PFBuS, 3.5 mmol | (12.762 | |
| | | moles amine) | |
| C | Ammonium Ad- | THEDA, 6.381 mmol | 34.9 mJ/cm² |
| | TFBS, 3.5 mmol | (12.762 | |
| | | moles amine) | |

1. A photoresist composition comprising:
(a) a resin;
(b) a photoacid generator;
(c) a thermal acid generator; and
(d) a basic component present in equivalent excess relative to the thermal acid generator.

2. A photoresist composition comprising:
(a) a resin;
(b) a photoacid generator;
(c) a thermal acid generator that produces an acid having a pKa of 2.0 or less during thermal treatment of a coating layer of the photoresist composition; and
(d) a basic component.

3. The photoresist composition of claim 1 wherein the thermal acid generator is a sulfonate salt.

4. The photoresist composition of claim 1 wherein the thermal acid generator comprises a fluorinated sulfonate component.

5. The photoresist composition of claim 1 wherein the thermal acid generator produces an acid having a pKa of less than 2.

6. The photoresist composition of claim 1 wherein the thermal acid generator does not contain an aromatic moiety

7. The photoresist composition of claim 1 wherein the ratio of equivalents of the thermal acid generator to equivalents of base from the basic component is between about 0.1-0.9.

8. The photoresist composition of claim 1 wherein the basic component is an amine-containing compound.

9. The photoresist composition of claim 1 wherein the basic component is a polyamine compound.

10. A method for forming a photoresist relief image comprising:
(a) applying a coating layer of a photoresist composition of claim 1 on a substrate;
(b) exposing the photoresist composition coating layer to patterned activating radiation and developing the exposed photoresist layer to provide a photoresist relief image.
